(19) United States
(12) Patent Application Publication
(10) Pub. No.: US 2026/0090007 A1
(43) Pub. Date: Mar. 26, 2026

(54) SEMICONDUCTOR STRUCTURE AND FABRICATION METHOD THEREOF

(71) Applicant: SwaySure Technology Co., Ltd., Shenzhen (CN)

(72) Inventor: Cheng-Hung Hsu, Shenzhen (CN)

(73) Assignee: SwaySure Technology Co., Ltd., Shenzhen (CN)

(21) Appl. No.: 19/263,336

(22) Filed: Jul. 8, 2025

(30) Foreign Application Priority Data
Sep. 23, 2024 (CN) 202411336417.5

(51) Int. Cl. H10D 30/63; H10D 30/01; H10D 62/10; H10D 64/01; H10D 64/66; H10D 64/68

(52) U.S. Cl. CPC H10D 30/63; H10D 30/025; H10D 62/102; H10D 64/015; H10D 64/021; H10D 64/679; H10D 64/691; H10D 64/693

(57) ABSTRACT

Disclosed are a semiconductor structure and a fabrication method thereof. The semiconductor structure includes a substrate; a gate structure, disposed on the substrate; a channel pillar, disposed on the substrate and extending through the gate structure in the longitudinal direction; a spacer, extending longitudinally between the sidewall of the channel pillar and the gate structure; a compensation layer, filling the void between the channel pillar and the gate structure at the bottom position of the spacer. The present disclosure facilitates improving the operating performance of the semiconductor structure.

### CROSS-REFERENCE TO RELATED APPLICATIONS

This application claims priority to Chinese Patent Application No. 202411336417.5, filed on Sep. 23, 2024, the entire disclosure of which is hereby incorporated herein by reference.

### TECHNICAL FIELD

Embodiments of the present disclosure relate to the field of semiconductor manufacturing, and in particular to a semiconductor structure and a fabrication method thereof.

### BACKGROUND

Semiconductor devices are integrated into packages to realize integrated circuit (IC) chips to match the conditions of use of various electronic products. In recent years, the need for integrated systems for specialized processing applications has increased in complex scenarios such as the Internet of Things and edge computing. Functionally integrated systems place demands on the integration of underlying materials. However, conventional semiconductor memory devices can be two-dimensional or planar semiconductor memory devices, and their degree of integration is an important factor in determining the price of the product.

In addition, the degree of integration is mainly dependent on the area occupied by a unit memory cell and is therefore strongly influenced by the level of fine pattern formation technology. However, the integration degree of two-dimensional semiconductor memory devices is improving but is still limited because miniaturization of patterns requires ultra-expensive equipment. Therefore, it is necessary to increase the integration level of semiconductor memory devices to meet the superior performance and low cost demanded by consumers.

### SUMMARY

The present disclosure provides a semiconductor structure and a fabrication method thereof, so as to improve the operating performance of the semiconductor structure.

A semiconductor structure is provided in some embodiments of the present disclosure. The semiconductor structure includes a substrate: a gate structure, disposed on the substrate; a channel pillar, disposed on the substrate and extending through the gate structure in the longitudinal direction: a spacer, extending longitudinally between the sidewall of the channel pillar and the gate structure: a compensation layer, filling the void between the channel pillar and the gate structure at the bottom position of the spacer.

Optionally, further comprising: a spacing layer, disposed between the spacer and the sidewall of the channel pillar: the compensation layer is also filled in the void between the channel pillar and the gate structure at the bottom position of the spacing layer.

Optionally, the spacing layer is a protective layer, the protective layer covers the sidewall of the spacer; or, the spacing layer is an air gap.

Optionally, the spacing layer is a protective layer, the material of the protective layer includes amorphous silicon, polycrystalline silicon, a combination of polycrystalline silicon with silicon oxide and tungsten or a combination of polycrystalline silicon with silicon oxide and titanium nitride.

Optionally; the compensation layer is further filled in a void defined by the top of the spacer and the spacing layer.

Optionally, the spacer comprises a first spacer covering the sidewall of the gate structure, and a second spacer covering the sidewall of the first spacer: at the bottom of the spacer, the void filled by the compensation layer is defined by the bottom of the second spacer, the bottom of the spacing layer, the first spacer, and the sidewall of the channel pillar: at the top of the spacer, the void filled by the compensation layer is defined by the top of the second spacer, the sidewall of the spacing layer, and the sidewall of the first spacer.

Optionally, the material of the compensation layer includes silicon nitride.

Optionally; further comprising: a top dielectric layer, covering the top surface of the gate structure: a bottom dielectric layer, disposed between the gate structure and the substrate: the channel pillar also extends through the top dielectric layer and bottom dielectric layer: the spacer also extends between the sidewall of the channel pillar and the top dielectric layer: the compensation layer is also filled in the void between the channel pillar and the bottom dielectric layer.

Optionally, on the top side of the channel pillar, a recess is formed in the channel pillar at a portion height, the semiconductor structure further comprising: an insulating layer, filled in the recess.

A fabrication method of a semiconductor structure is further provided in some embodiments of the present disclosure. The method includes providing a substrate, the substrate having a gate structure formed thereon: forming an opening through the gate structure: forming a spacer covering the sidewall of the opening: performing a void compensation treatment at the bottom corner of the opening to form a compensation layer that fills the void at the bottom of the spacer: forming a channel pillar disposed on the substrate and extending through the gate structure in the opening.

Optionally, before performing the void compensation treatment at the bottom corner of the opening, further comprising: forming a protective layer covering the sidewall of the spacer: in the step of performing the void compensation treatment at the bottom corner of the opening, the compensation layer is further filled in the void at the bottom of the protective layer at the bottom corner of the opening: in the step of forming the channel pillar disposed on the substrate and extending through the gate structure in the opening, the channel pillar is in contact with the protective layer.

Optionally, after forming the channel pillar disposed on the substrate and extending through the gate structure in the opening, further comprising: removing the protective layer to form an air gap disposed between the spacer and the sidewall of the channel pillar.

Optionally; in the step of performing the void compensation treatment at the bottom corner of the opening, the compensation layer is also filled in the void defined by the top of the spacer and the protective layer.

Optionally; the step of forming the spacer covering the sidewall of the opening comprises: forming a spacer material layer covering the sidewall and bottom of the opening, and the top of the gate structure; removing the spacer material layer at the bottom of the opening and at the top of the gate structure, and retaining the spacer material layer covering the sidewall of the opening as the spacer.

Optionally, in the step of providing the substrate, a top dielectric layer is also formed on top of the gate structure, and a bottom dielectric layer is also formed between the gate structure and the substrate: in the step of forming an opening through the gate structure, the opening also extends through the top dielectric layer, and the opening also extends through a portion thickness of the bottom dielectric layer: in the step of removing the spacer material layer at the bottom of the opening and at the top of the gate structure, further comprises: removing the remaining portion of the thickness of the bottom dielectric layer to expose the top surface of the substrate: in the step of performing the void compensation treatment at the bottom corner of the opening, the compensation layer is further filled in the void defined by the bottom dielectric layer and the substrate at the bottom corner of the opening.

Optionally, the step of forming the spacer material layer covering the sidewall and bottom of the opening, and the top of the gate structure comprises: forming a first spacer material layer covering the sidewall and bottom of the opening, and the top of the gate structure: forming a second spacer material layer covering the first spacer material layer: in the step of removing the spacer material layer at the bottom of the opening and at the top of the gate structure, the first spacer material layer and the second spacer material layer at the bottom of the opening and at the top of the gate structure are removed, the first spacer material layer covering the sidewall of the opening being retained as a first spacer, and the second spacer material layer covering the sidewall of the opening being retained as a second spacer: in the step of performing the void compensation treatment at the bottom corner of the opening, the compensation layer is filled in the void defined by the bottom of the second spacer, the bottom of the protective layer, and the first spacer, and the compensation layer is further filled in the void defined by the top of the second spacer, the sidewall of the protective layer, and the sidewall of the first spacer.

Optionally, before removing the spacer material layer at the bottom of the opening and at the top of the gate structure, further comprising: forming a protective material layer covering the spacer material layer; the step of removing the spacer material layer at the bottom of the opening and at the top of the gate structure further comprises: removing the protective material layer at the bottom of the opening and at the top of the gate structure, retaining the protective material layer covering the sidewall of the spacer as the protective layer.

Optionally, using a dry etching process to remove the spacer material layer at the bottom of the opening and at the top of the gate structure: after removing the spacer material layer at the bottom of the opening and at the top of the gate structure, and before performing the void compensation treatment at the bottom corner of the opening, further comprising: performing a cleaning treatment on the spacer.

Optionally, the step of performing the void compensation treatment at the bottom corner of the opening to form the compensation layer that fills the void at the bottom of the spacer comprises: forming a compensating material layer covering the bottom of the opening, the sidewall of the spacer on the sidewall of the opening, the top of the gate structure, and filling the void at the bottom of the spacer: removing the compensating material layer covering the bottom of the opening, the sidewall of the spacer on the sidewall of the opening, and the top of the gate structure, and retaining the compensating material layer that fills the void at the bottom of the spacer as the compensation layer.

Optionally, in the step of forming the channel pillar disposed on the substrate and extending through the gate structure in the opening, the channel pillar fills the opening: or, in the step of forming the channel pillar disposed on the substrate and extending through the gate structure in the opening, on the top side of the channel pillar, a recess is formed in the channel pillar at a portion height: forming an insulating layer that fills the recess.

The technical solutions in some embodiments of the present disclosure have the advantages as follows:

In the semiconductor structure according to some embodiments of the present disclosure, a channel pillar disposed on the substrate and extending through the gate structure in the longitudinal direction, a spacer extending longitudinally between the sidewall of the channel pillar and the gate structure, a compensation layer filling the void between the channel pillar and the gate structure at the bottom position of the spacer: in the semiconductor structure according to the embodiments of the present disclosure, the compensation layer is filled in the void between the channel pillar and the gate structure at the bottom position of the spacer, so as to be able to utilize the compensation layer to compensate for the isolation performance between the gate structure and the channel pillar at the bottom of the spacer, which is beneficial for ensuring the insulation effect between the gate structure and the channel pillar, thus helping to reduce the leakage effect between the gate structure and the channel pillar, which is beneficial for ensuring that the semiconductor structure meets the process requirements for threshold voltage, and for reducing the probability of drain-induced barrier lowering (DIBL) in the semiconductor structure. This, in turn, is advantageous for ensuring the operational performance of the semiconductor structure.

In the fabrication method according to some embodiments of the present disclosure, forming an opening through the gate structure, forming a spacer covering the sidewall of the opening, performing a void compensation treatment at the bottom corner of the opening to form a compensation layer that fills the void at the bottom of the spacer, forming a channel pillar disposed on the substrate and extending through the gate structure in the opening: in the fabrication method according to the embodiments of the present disclosure, performing a void compensation treatment at the bottom corner of the opening, so as to be able to utilize the compensation layer to compensate for the isolation performance between the gate structure and the channel pillar at the bottom of the spacer, which is beneficial for ensuring the insulation effect between the gate structure and the channel pillar, thus helping to reduce the leakage effect between the gate structure and the channel pillar, which is beneficial for ensuring that the semiconductor structure meets the process requirements for threshold voltage, and for reducing the probability of drain-induced barrier lowering (DIBL) in the semiconductor structure. This, in turn, is advantageous for ensuring the operational performance of the semiconductor structure.

### BRIEF DESCRIPTION OF THE DRAWINGS

FIG. 1 is a schematic structural diagram corresponding to a semiconductor structure;

FIG. 2 is a schematic structural diagram corresponding to an embodiment of a semiconductor structure according to the present disclosure;

FIG. 3 is a schematic structural diagram corresponding to another embodiment of a semiconductor structure according to the present disclosure;

FIG. 4 is a schematic structural diagram corresponding to yet another embodiment of a semiconductor structure according to the present disclosure:

FIGS. 5 to 12 are schematic structural diagrams corresponding to each step in an embodiment of a fabrication method of a semiconductor structure according to the present disclosure:

FIGS. 13 to 15 are schematic structural diagrams corresponding to each step in another embodiment of a fabrication method of a semiconductor structure according to the present disclosure; and

FIG. 16 is a schematic structural diagram corresponding to each step in yet another embodiment of a fabrication method of a semiconductor structure according to the present disclosure.

### DETAILED DESCRIPTION

As can be seen from the background technology, it is currently difficult to guarantee the working performance of a semiconductor structure. The reasons why the operating performance of semiconductor structures still needs to be improved are analyzed in relation to a semiconductor structure.

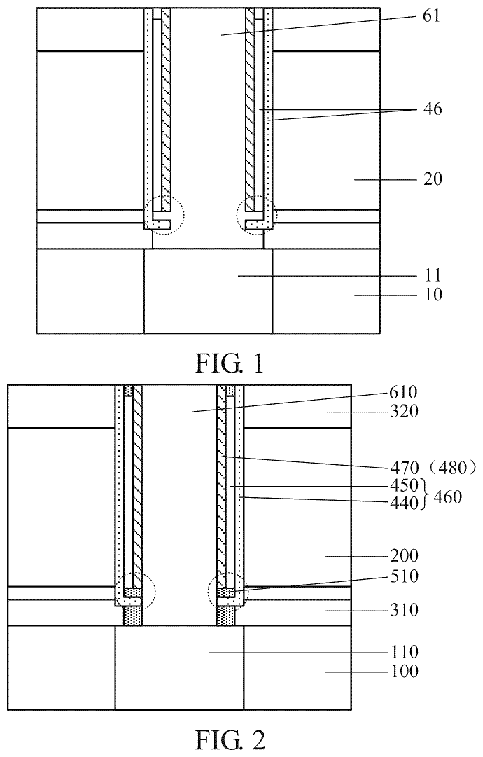

FIG. 1 illustrates a schematic structural diagram corresponding to a semiconductor structure.

Referring to FIG. 1, the semiconductor structure includes a substrate 10, having a source-drain doping layer 11 formed in the substrate 10; a gate structure 20, disposed on the substrate 10; a channel pillar 61, disposed on the source-drain doping layer 11 in the substrate 10 and running longitudinally through the gate structure 20; and a spacer 46, extending longitudinally between the sidewall of the channel pillar 61 and the gate structure 20.

In the semiconductor process, the process of forming the spacer 46 is prone to damage at the bottom of the spacer 46, which results in the absence of the spacer 46 at the bottom position of the channel pillar 61 (shown as a dotted circle in FIG. 1), then the isolation performance between the channel pillar 61 and the gate structure 20 at the bottom position of the spacer 46 is poor, which is prone to result in the generation of an Off-state Leakage Current (Ioff) between the gate structure 20 and the channel pillar 61, which affects the threshold voltage (Vt) of the semiconductor structure, leading to a decrease in a drain induced barrier low (DIBL) of the semiconductor structure, thereby affecting the operating performance of the semiconductor structure.

In order to solve the technical problem, a semiconductor structure is provided in the embodiments of the present disclosure. The semiconductor structure includes a substrate: a gate structure, disposed on the substrate: a channel pillar, disposed on the substrate and extending through the gate structure in the longitudinal direction: a spacer, extending longitudinally between the sidewall of the channel pillar and the gate structure: a compensation layer, filling the void between the channel pillar and the gate structure at the bottom position of the spacer.

In the semiconductor structure according to some embodiments of the present disclosure, the compensation layer is filled in the void between the channel pillar and the gate structure at the bottom position of the spacer, so as to be able to utilize the compensation layer to compensate for the isolation performance between the gate structure and the channel pillar at the bottom of the spacer, which is beneficial for ensuring the insulation effect between the gate structure and the channel pillar, thus helping to reduce the leakage effect between the gate structure and the channel pillar, which is beneficial for ensuring that the semiconductor structure meets the process requirements for threshold voltage, and for reducing the probability of drain-induced barrier lowering (DIBL) in the semiconductor structure. This, in turn, is advantageous for ensuring the operational performance of the semiconductor structure.

To make the above objectives, features, and advantages in the embodiments of the present disclosure more apparent and easier to understand, specific embodiments of the present disclosure are described in detail below with reference to the accompanying drawings.

FIG. 2 is a schematic structural diagram corresponding to an embodiment of a semiconductor structure according to the present disclosure.

Referring to FIG. 2, the semiconductor structure includes a substrate 100; a gate structure 200, disposed on the substrate 100: a channel pillar 610, disposed on the substrate 100 and extending through the gate structure 200 in the longitudinal direction: a spacer 460, extending longitudinally between the sidewall of the channel pillar 610 and the gate structure 200; and a compensation layer 510, filling the void between the channel pillar 610 and the gate structure 200 at the bottom position of the spacer 460.

The substrate 100 provides a process operation basis for the process of forming semiconductor structures.

In one embodiment, the substrate 100 is a dielectric material, specifically, the material of the substrate 100 includes silicon oxide or silicon nitride. As an example, In one embodiment, the material of the substrate 100 is silicon oxide.

The gate structure 200 is used to control the turning on and off of the channel of the transistor.

In one embodiment, the gate structure 200 is a metal gate structure, specifically, the material of the gate structure 200 includes one or more of TiN, TaN, Ta, Ti, TiAl, W, Al, TiSiN, and TiAlC. As an example, in one embodiment, the material of the gate structure 200 is W.

The channel pillar 610 is used as the channel of the transistor.

Specifically, in one embodiment, the channel pillar 610 extends along the longitudinal direction through the gate structure 200, constituting a vertical channel transistor (VCT), which improves the integration degree of the transistor through the vertical channel design, allowing more transistors to be integrated in the same wafer area, and thus improves the performance and efficiency of the chip.

In one embodiment, the material of the channel pillar 610 includes silicon, germanium, silicon germanide, or a III-V semiconductor material. As an example, In one embodiment, the material of the channel pillar 610 is silicon. In other embodiments, the material of the channel pillar is determined based on the type and performance of the transistor.

The spacer 460 is used to isolate the gate structure 200 from the channel pillar 610.

In one embodiment, the spacer 460 comprises a first spacer 440 covering the sidewall of the gate structure 200, and a second spacer 450 covering the sidewall of the first spacer 440.

Using the first spacer 440 and the second spacer 450 to form the spacer 460 is helpful to safeguard the isolating effect of the spacer 460, and is also capable of adjusting the dielectric constant of the spacer 460 by the first spacer 440 and the second spacer 450.

Specifically, in one embodiment, the material of the first spacer 440 includes silicon nitride, and the material of the second spacer 450 includes silicon oxide.

In one embodiment, the thickness of the first spacer 440 is from 1 nm to 8 nm, which is conducive to making the first spacer 440 have sufficient thickness to safeguard the isolation performance of the spacer 460, and the first spacer 440 does not occupy too much space to meet the integration degree of the semiconductor structure.

In one embodiment, the thickness of the second spacer 450 is from 1 nm to 8 nm, which is conducive to making the second spacer 450 sufficiently thick to safeguard the isolation performance of the spacer 460, and the second spacer 450 does not occupy too much space to satisfy the integration degree of the semiconductor structure.

The compensation layer 510 is filled in the void between the channel pillar 610 and the gate structure 200 at the bottom position of the spacer 460 (as shown by the dotted circle in FIG. 2) to compensate for the isolation effect between the gate structure 200 and the channel pillar 610 at the bottom of the spacer 460.

In one embodiment, the compensation layer 510 is filled in the void between the channel pillar 610 and the gate structure 200 at the bottom position of the spacer 460, so as to be able to utilize the compensation layer 510 to compensate for the isolation performance between the gate structure 200 and the channel pillar 610 at the bottom of the spacer 460, which is beneficial for ensuring the insulation effect between the gate structure 200 and the channel pillar 610, thus helping to reduce the leakage effect between the gate structure 200 and the channel pillar 610, which is beneficial for ensuring that the semiconductor structure meets the process requirements for threshold voltage, and for reducing the probability of drain-induced barrier lowering (DIBL) in the semiconductor structure. This, in turn, is advantageous for ensuring the operational performance of the semiconductor structure.

It should be noted that in the semiconductor process, the bottom of the spacer 460 is susceptible to void formation due to process damage, and therefore, the compensation layer 510 fills the void between the channel pillar 610 and the gate structure 200 at the bottom position of the spacer 460.

In one embodiment, the material of the compensation layer 510 includes silicon nitride.

The use of silicon nitride to form the compensation layer 510 can achieve a better isolation effect, and the silicon nitride is harder and less damaged in the semiconductor process, which can guarantee the isolation effect of the compensation layer 510.

In one embodiment, the semiconductor structure further comprises: a spacing layer 480, disposed between the spacer 460 and the sidewall of the channel pillar 610.

The spacing layer 480 is between the spacer 460 and the sidewall of the channel pillar 610, and the region of the spacing layer 480 is used to provide protection for the spacer 460 during the process of forming the channel pillar 610.

In one embodiment, the compensation layer 510 is also filled in the void between the channel pillar 610 and the gate structure 200 at the bottom position of the spacing layer 480.

Specifically, in the semiconductor process, the region of the spacing layer 480 covers the sidewall of the spacer 460, then the formation process of the spacer 460 will cause damage to the spacer 460 through the bottom of the region of the spacing layer 480, so that accordingly, the compensation layer 510 is also filled in the void between the channel pillar 610 and the gate structure 200 at the bottom position of the spacing layer 480.

In one embodiment, the spacing layer 480 has a thickness of 3 nm to 12 nm.

The thickness of the spacing layer 480 is from 3 nm to 12 nm, which is conducive to reducing the difficulty of forming the spacing layer 480, and is also conducive to making the spacer 460 sufficiently protected.

In one embodiment, the compensation layer 510 is further filled in a void defined by the top of the spacer 460 and the spacing layer 480.

It should be noted that in the semiconductor process, where the top of the spacer 460 is also exposed by the spacing layer 480, the top of the spacer 460 is also prone to forming a void due to process damage, and therefore the compensation layer 510 is further filled in a void defined by the top of the spacer 460 and the spacing layer 480.

Specifically, In one embodiment, at the bottom of the spacer 460, the void filled by the compensation layer 510 is defined by the bottom of the second spacer 450, the bottom of the spacing layer 480, the first spacer 440, and the sidewall of the channel pillar 610; at the top of the spacer 460, the void filled by the compensation layer 510 is defined by the top of the second spacer 450, the sidewall of the spacing layer 480, and the sidewall of the first spacer 440.

It is to be noted that in the semiconductor process, the spacer 460 covering the sidewalls of the gate structure 200 is formed first, and then the channel pillar 610 are formed between the spacer 460, then in the process of the spacer 460, the second spacer 450 is closer to the region of the process operation as compared to the first spacer 440, so that the second spacer 450 is more susceptible to damage, moreover, the material of the first spacer 440 includes silicon nitride, the material of the second spacer 450 includes silicon oxide, and the silicon oxide is more susceptible to damage compared to silicon nitride, i.e., the top and bottom of the second spacer 450 are susceptible to removal of portions of the second spacer 450 by the process damage, and, thus, at the bottom of the spacer 460, the void filled by the compensation layer 510 is defined by the bottom of the second spacer 450, the bottom of the spacing layer 480, the first spacer 440, and the sidewall of the channel pillar 610; at the top of the spacer 460, the void filled by the compensation layer 510 is defined by the top of the second spacer 450, the sidewall of the spacing layer 480, and the sidewall of the first spacer 440.

In one embodiment, the spacing layer 480 is a protective layer 470, and the protective layer 470 covers the sidewall of the spacer 460.

The protective layer 470 is used to protect the spacer 460 during the process of forming the spacer 460 to minimize damage to the spacer 460.

In one embodiment, the material of the protective layer 470 includes amorphous silicon, polycrystalline silicon, a combination of polycrystalline silicon with silicon oxide and tungsten or a combination of polycrystalline silicon with silicon oxide and titanium nitride.

The use of amorphous silicon, polycrystalline silicon, a combination of polycrystalline silicon and silicon oxide and tungsten, or a combination of polycrystalline silicon and silicon oxide and titanium nitride to form the protective layer 470 can provide a better protection, and retaining the protective layer 470 on both sides of the channel pillar 610 will not introduce other elements that are easy to contaminate, which is conducive to safeguarding the basic operating performance of the transistor.

In one embodiment, the semiconductor structure further comprises: a top dielectric layer 320, covering the top surface of the gate structure 200.

The top dielectric layer 320 is used to insulate the gate structure 200 from other device structures above it.

In one embodiment, the material of the top dielectric layer 320 is an insulating material including one or more of silicon oxide, silicon nitride, silicon nitride oxide, silicon carbon oxide, silicon carbon nitride, and silicon carbon nitride oxide.

Accordingly, in one embodiment, the spacer 460 also extends between the sidewall of the channel pillar 610 and the top dielectric layer 320.

In one embodiment, the semiconductor structure further comprises: a bottom dielectric layer 310, disposed between the gate structure 200 and the substrate 100.

The bottom dielectric layer 310 is used to insulate the gate structure 200 from other device structures below it.

In one embodiment, the material of the bottom dielectric layer 310 is an insulating material including one or more of silicon oxide, silicon nitride, silicon nitride oxide, silicon carbon oxide, silicon carbon nitride, and silicon carbon nitride oxide.

Accordingly, in one embodiment, the channel pillar 610 also extends through the top media layer 320 and the bottom media layer 310.

In one embodiment, the compensation layer 510 is also filled in the void between the channel pillar 610 and the bottom dielectric layer 310.

In a semiconductor process in which a protective layer 470 covering the spacer 460 is formed first, and then a region for forming the channel pillar 610 is formed through the bottom dielectric layer 310, the sidewalls of the bottom dielectric layer 310 are also exposed during the process operation, and thus the bottom dielectric layer 310 is also partially damaged by the process operation, and thus, in the process for forming the compensation layer 510, the compensation layer 510 is also filled in the void between the channel pillar 610 and the bottom dielectric layer 310.

In one embodiment, the semiconductor structure further comprises: a source-drain doping layer 110, disposed in the substrate 100, with the top surface of the substrate 100 exposing the source-drain doping layer 110.

The source-drain doping layer 110 is used as a source or drain region of a transistor. Specifically, the doping type of the source-drain doping layer 110 is the same as the channel conductivity type of the corresponding transistor.

In one embodiment, the top surface of the substrate 100 exposes the source-drain doping layer 110 for causing the channel pillars 610 disposed on the substrate 100 to contact the source-drain doping layer 110.

Accordingly, in one embodiment, the channel pillar 610 is disposed on and in contact with the source-drain doping layer 110.

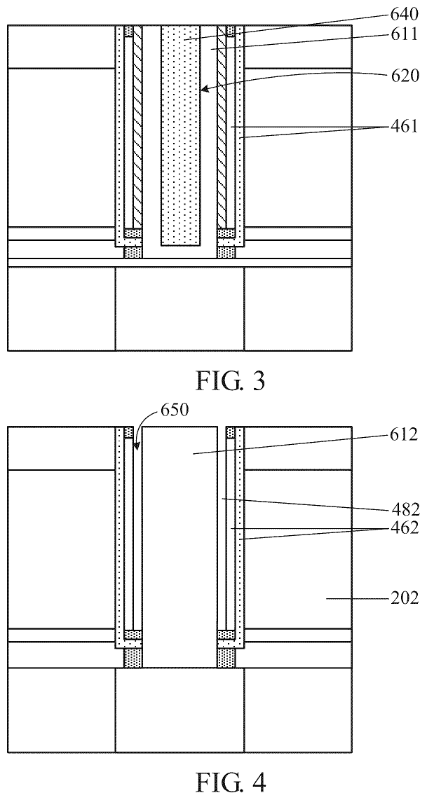

FIG. 3 is a schematic structural diagram corresponding to another embodiment of a semiconductor structure according to the present disclosure.

The similarities between this embodiment and the preceding embodiment will not be repeated herein.

The present embodiment differs from the preceding embodiment in that the structure of the channel pillar is different.

Referring to FIG. 3, on the top side of the channel pillar 611, a recess 620 is formed in the channel pillar 611 at a portion height, and the semiconductor structure further comprises: an insulating layer 640, filled in the recess 620.

The fact that the channel pillar 611 does not fill the area between the spacer 461 and that the recess 620 are filled with an insulating layer 640 facilitates obtaining a top surface of the channel pillar 611 with a better surface flatness.

In one embodiment, the material of the insulating layer 640 is an insulating material including one or more of silicon oxide, silicon nitride, silicon nitride oxide, silicon carbon oxide, silicon carbon nitride, and silicon carbon nitride oxide.

FIG. 4 is a schematic structural diagram corresponding to yet another embodiment of a semiconductor structure according to the present disclosure.

The similarities between this embodiment and the preceding embodiments will not be repeated herein. The present embodiment differs from the preceding embodiments in that the spacing layer has a different structure.

Referring to FIG. 4, the spacing layer 482 is an air gap 650.

The air gap 650 is used to serve, along with the sidewall 462, to isolate the gate structure 202 from the channel pillar 612.

Specifically, in one embodiment, a protective layer is pre-formed to occupy the location, and after forming the channel pillar 612, the protective layer is removed to form the air gap 650.

In one embodiment, the air gap 650 and the spacer 462 together isolate the gate structure 202 from the channel pillar 612, and the dielectric constant of the air is low, then the use of the air gap 650 together with the spacer 462 to isolate the gate structure 202 from the channel pillar 612 is conducive to lowering the dielectric constant of the overall isolation between the gate structure 202 and the channel pillar 612, which is conducive to lowering the parasitic capacitance and improving the semiconductor structure's operating performance.

FIGS. 5 to 12 are schematic structural diagrams corresponding to each step in an embodiment of a fabrication method of a semiconductor structure according to the present disclosure.

Referring to FIG. 5, providing a substrate 100, the substrate 100 having a gate structure 200 formed thereon.

The substrate 100 provides a process operation basis for the process of forming semiconductor structures.

In one embodiment, the substrate 100 is a dielectric material, specifically, the material of the substrate 100 includes silicon oxide or silicon nitride. As an example, in one embodiment, the material of the substrate 100 is silicon oxide.

The gate structure 200 is used to control the turning on and off of the channel of the transistor.

In one embodiment, the gate structure 200 is a metal gate structure, specifically, the material of the gate structure 200 includes one or more of TIN, TaN, Ta, Ti, TiAl, W, Al, TiSiN, and TiAlC. As an example, in one embodiment, the material of the gate structure 200 is W.

In one embodiment, in the step of providing the substrate 100, a top dielectric layer 320 is also formed on top of the gate structure 200, and a bottom dielectric layer 310 is also formed between the gate structure 200 and the substrate 100.

The top dielectric layer 320 is used to insulate the gate structure 200 from other device structures above it.

In one embodiment, the material of the top dielectric layer 320 is an insulating material including one or more of silicon oxide, silicon nitride, silicon nitride oxide, silicon carbon oxide, silicon carbon nitride, and silicon carbon nitride oxide.

The bottom dielectric layer 310 is used to insulate the gate structure 200 from other device structures below it.

In one embodiment, the material of the bottom dielectric layer 310 is an insulating material including one or more of silicon oxide, silicon nitride, silicon nitride oxide, silicon carbon oxide, silicon carbon nitride, and silicon carbon nitride oxide.

In one embodiment, in the step of providing the substrate 100, a source-drain doping layer 110 is also formed in the substrate 100, with the top surface of the substrate 100 exposing the source-drain doping layer 110.

The source-drain doping layer 110 is used as a source or drain region of a transistor. Specifically, the doping type of the source-drain doping layer 110 is the same as the channel conductivity type of the corresponding transistor.

In one embodiment, the top surface of the substrate 100 exposes the source-drain doping layer 110 for enabling subsequent channel pillars formed on the substrate 100 to contact the source-drain doping layer 110.

With continued reference to FIG. 5, forming an opening 210 through the gate structure 200.

The opening 210 is used to provide a spatial location for the subsequent formation of spacer and channel pillar.

Accordingly, in one embodiment, in the step of forming the opening 210 through the gate structure 200, the opening 210 also extends through the top dielectric layer 320, and the opening 210 also extends through a portion thickness of the bottom dielectric layer 310.

The opening 210 extends through a portion thickness of the bottom media layer 310, retaining the remaining portion thickness of the bottom media layer 310 to cover the top surface of the source-drain doping layer 110 to serve as protection for the source-drain doping layer 110 in subsequent steps of forming the spacer.

In one embodiment, in the step of forming the opening 210 through the gate structure 200, the opening 210 is formed above the source-drain doping layer 110.

An opening 210 is formed above the source-drain doping layer 110 to enable a subsequently formed channel pillar to contact the source-drain doping layer 110.

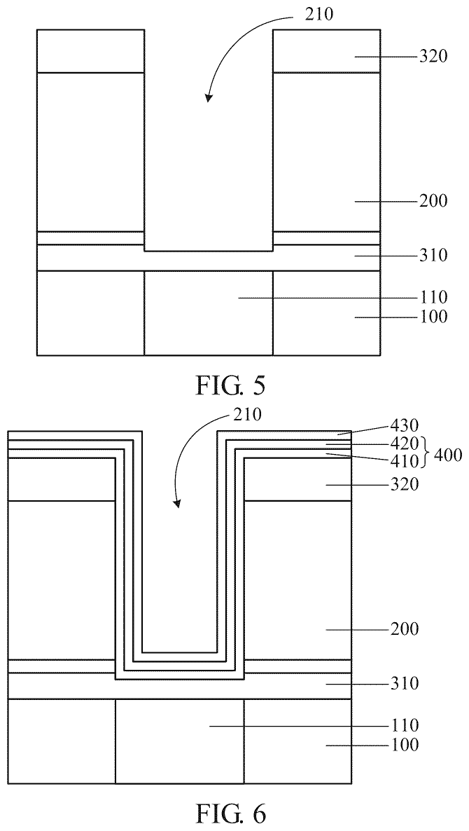

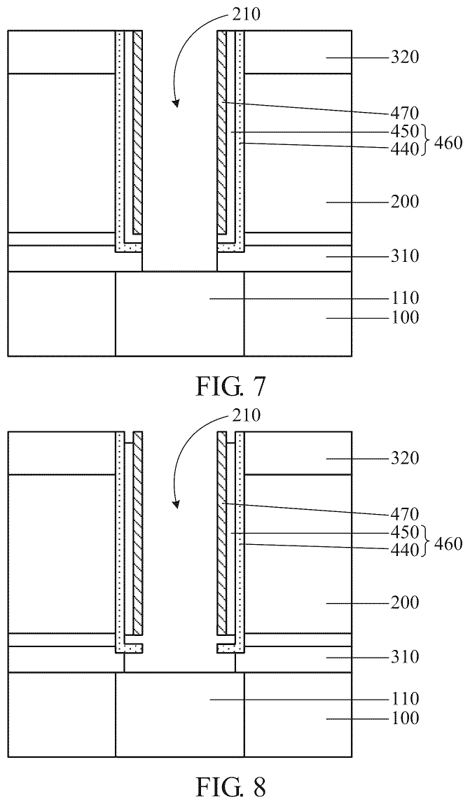

Referring to FIGS. 6 to 7, forming a spacer 460 covering the sidewall of the opening 210.

The spacer 460 is used to isolate the gate structure 200 from the subsequently formed channel pillar.

Referring to FIG. 6, the step of forming a spacer 460 covering the sidewall of the opening 210 comprises: forming a pacer material layer 400 covering the sidewall and bottom of the opening 210, and the top of the gate structure 200.

The pacer material layer 400 is used to form the spacer 460.

Specifically, in one embodiment, the step of forming the pacer material layer 400 covering the sidewall and bottom of the opening 210, and the top of the gate structure 200 comprises: forming a first spacer material layer 410 covering the sidewall and bottom of the opening 210, and the top of the gate structure 200.

The first spacer material layer 410 is used to form a first spacer.

In one embodiment, the material of the first spacer material layer 410 includes silicon nitride.

In one embodiment, in the step of forming the first spacer material layer 410 covering the sidewall and bottom of the opening 210 and the top of the gate structure 200, the thickness of the first spacer material layer 410 is 1 nm to 8 nm, which is favorable for making the subsequently formed first spacer have a sufficient thickness to safeguard the isolation performance of the spacer 460, and the first spacer will not occupy an excessively large space to meet the semiconductor structure's integration degree.

In one embodiment, forming a second spacer material layer 420 covering the first spacer material layer 410.

Specifically, the second spacer material layer 420 conformally covers the first spacer material layer 410, and the second spacer material layer 420 is used to form a second spacer.

In one embodiment, the material of the second spacer material layer 420 includes silicon oxide.

In one embodiment, in the step of forming the second spacer material layer 420 covering the first spacer material layer 410, the second spacer material layer 420 has a thickness of 1 nm to 8 nm, which is conducive to making the subsequently formed second spacer have a sufficient thickness to safeguard the isolation performance of the spacer 460, and the second spacer will not occupy an excessively large space to satisfy the degree of integration of the semiconductor structure.

Referring to FIG. 7, removing the spacer material layer 400 at the bottom of the opening 210 and at the top of the gate structure 200 is removed, and retaining the spacer material layer 400 covering the sidewall of the opening as the spacer 460.

In one embodiment, a dry etching process is used to remove the spacer material layer 400 at the bottom of the opening 210 and at the top of the gate structure 200.

The dry etching process has anisotropic etching characteristics, so by selecting the dry etching process, it is favorable to reduce the damage to the substrate 100 at the bottom of the opening 210, and at the same time, the dry etching has more etching directionality, which is favorable to improving the topographic quality and dimensional accuracy of the spacer 460.

Specifically, in one embodiment, in the step of removing the spacer material layer 400 at the bottom of the opening 210 and at the top of the gate structure 200, the first sidewall spacer layer 410 and the second spacer material layer 420 at the bottom of the opening 210 and at the top of the gate structure 200 are removed, and the first spacer material layer 410 covering the sidewall of the opening 210 is retained as the first spacer 440, and the second spacer material layer 420 is retained as a second spacer 450.

The use of the first spacer 440 and the second spacer 450 to form the spacer 460 is helpful to safeguard the isolating effect of the spacer 460, and is also capable of adjusting the dielectric constant of the spacer 460 by the first spacer 440 and the second spacer 450.

Specifically, in one embodiment, the material of the first spacer 440 includes silicon nitride, and the material of the second spacer 450 includes silicon oxide.

In one embodiment, before performing the void compensation treatment at the bottom corner of the opening 210, further comprising: forming a protective layer 470 covering the sidewall of the spacer 460.

The protective layer 470 is used to protect the spacer 460 during the process of forming the spacer 460 to minimize damage to the spacer 460.

In one embodiment, in the step of forming a protective layer 470 covering the sidewall of the spacer 460, the material of the protective layer 470 includes amorphous silicon, polycrystalline silicon, a combination of polycrystalline silicon with silicon oxide and tungsten, or a combination of polycrystalline silicon with silicon oxide and titanium nitride.

The use of amorphous silicon, polycrystalline silicon, a combination of polycrystalline silicon and silicon oxide and tungsten, or a combination of polycrystalline silicon and silicon oxide and titanium nitride to form a protective layer 470 can play a better protective role, and the subsequent formation of channel pillar, the protective layer 470 will be retained on both sides of the channel pillar that will not be introduced into the easy to contaminate other elements, which is conducive to safeguarding the basic working performance of the transistor.

Specifically, referring to FIG. 6, before removing the spacer material layer 400 at the bottom of the opening 210 and at the top of the gate structure 200, further comprising: forming a protective material layer 430 covering the spacer material layer 400.

Specifically, the protective material layer 430 conformally covers the spacer material layer 400, and the protective material layer 430 is used to form the protective layer 470.

Referring to FIG. 7, the step of removing the spacer material layer 400 at the bottom of the opening 210 and at the top of the gate structure 200 further comprises: removing the protective material layer 430 at the bottom of the opening 210 and at the top of the gate structure 200, retaining the protective material layer 430 covering the sidewall of the spacer 460 as the protective layer 470.

Specifically, in one embodiment, a dry etching process is used to remove the protective material layer 430 from the bottom of the opening 210 and the top of the gate structure 200.

In one embodiment, the step of removing the spacer material layer 400 at the bottom of the opening 210 and at the top of the gate structure 200 further comprises: removing the remaining portion thickness of the bottom dielectric layer 310 to expose the top surface of the substrate 100.

Specifically, in one embodiment, the remaining portion of the thickness of the bottom dielectric layer 310 is removed to expose the top surface of the source-drain doping layer 110 of the substrate 100 in preparation for the subsequent formation of channel pillar in contact with the source-drain doping layer 110.

Referring to FIG. 8, after removing the spacer material layer 400 at the bottom of the opening 210 and at the top of the gate structure 200, and before performing the void compensation treatment at the bottom corner of the opening 210, further comprising: performing a cleaning process on the spacer 460.

The process of forming the spacer 460 is prone to cause residue residue, especially prone to have residue residue in the bottom of the opening 210, especially for the present embodiment, where a dry etching process is used to form the spacer 460 and the protective layer 470, and it is prone to have residue of the dry etching in the opening 210, therefore, a cleaning process is carried out for the spacer 460 in order to remove residue in the opening 210 to reduce contamination of the subsequent process and also to provide a better process platform for the subsequent process.

It should be noted that the cleaning treatment of the spacer 460 causes damage to the top and bottom of the spacer 460 exposed by the protective layer 470. Specifically, the material of the first spacer 440 is silicon nitride, and the material of the second spacer 450 is silicon oxide, and the silicon oxide is more susceptible to damage, and thus the cleaning treatment removes a portion of the second spacer 450 at the top position of the spacer 460 and a portion of the second spacer 450 at the bottom position of the spacer 460. At the same time, the opening 210 also penetrates the bottom media layer 310, i.e., the opening 210 also exposes the bottom media layer 310, and therefore, the cleaning treatment will also remove a portion of the bottom media layer 310 at the bottom corners of the opening 210.

In one embodiment, the cleaning solution for the cleaning treatment is a diluted Hydrofluoric Acid (DHF) solution.

Dilute hydrofluoric acid solution etching rate is slower and more stable, better for cleaning and less damage to the film layer, and it should be noted that fluorine-containing cleaning solution is easy to cause etching damage to the silicon oxide.

Specifically, in one embodiment, the diluted hydrofluoric acid solution has a volume ratio of water to hydrofluoric acid of 100:1 to 2000:1.

In other embodiments, the cleaning solution for the cleaning treatment may also be a dilute hydrogen peroxide sulfate (DSP) mixture or SST-A47 organic solution.

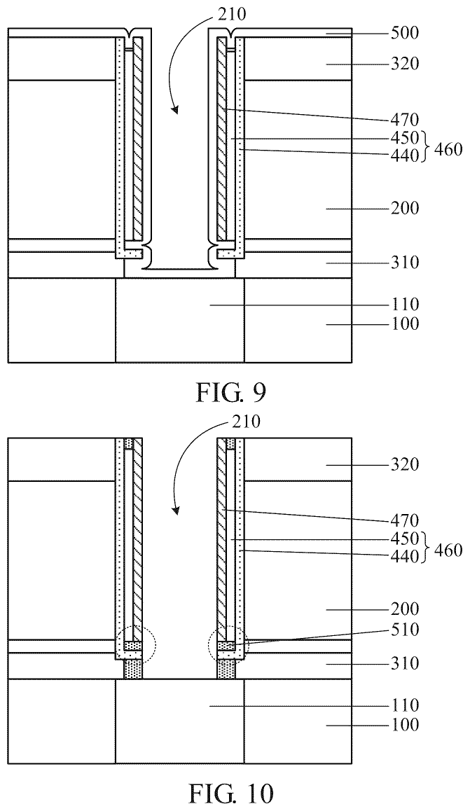

Referring to FIGS. 9 to 10, performing a void compensation treatment at the bottom corner of the opening 210 to form a compensation layer 510 that fills the void at the bottom of the spacer 460 (as shown by the dotted circle in FIG. 10).

The compensation layer 510 fills the bottom of the spacer 460 at the bottom corners of the opening 210, and channel pillar will subsequently be formed in the opening 210, i.e., the compensation layer 510 compensates for the isolation effect between the subsequently formed channel pillar and the gate structure 200 for compensating for the isolation effect between the gate structure 200 and the channel pillar at the bottom of the spacer 460.

In one embodiment, performing a void compensation treatment at the bottom corner of the opening 210, so as to be able to utilize the compensation layer 510 to compensate for the isolation performance between the gate structure 200 and the channel pillar at the bottom of the spacer 460, which is beneficial for ensuring the insulation effect between the gate structure 200 and the channel pillar, thus helping to reduce the leakage effect between the gate structure 200 and the channel pillar, which is beneficial for ensuring that the semiconductor structure meets the process requirements for threshold voltage, and for reducing the probability of drain-induced barrier lowering (DIBL) in the semiconductor structure. This, in turn, is advantageous for ensuring the operational performance of the semiconductor structure.

In one embodiment, the bottom of the spacer 460 exposed through the protective layer 470 causes damage to the spacer 460 during the cleaning treatment of the spacer 460, therefore, in the step of performing the void compensation treatment at the bottom corner of the opening 210, the compensation layer 510 is further filled in the void at the bottom of the protective layer 470 at the bottom corner of the opening 210.

In one embodiment, the cleaning treatment of the spacer 460 also causes damage to the spacer 460 through the top of the spacer 460 exposed by the protective layer 470, and therefore, in the step of performing the void compensation treatment at the bottom corner of the opening 210, the compensation layer is also filled in the void defined by the top of the spacer 460 and the protective layer 470.

Specifically, in one embodiment, the material of the second spacer 450 is silicon oxide, and the material of the first spacer 440 is silicon nitride, and the silicon oxide is easily damaged, then a void is constituted by the removal of a portion of the second spacer 450 from the top and the bottom, and therefore, in a step of performing a void compensation treatment at the corner of the bottom of the opening 210, the compensation layer 510 is filled in a void defined by the bottom of the second spacer 450, the bottom of the protective layer 470 and the first spacer 440, and the compensation layer 510 is also filled in the void defined by the top of the second spacer 450, the sidewall of the protective layer 470, and the sidewall of the first spacer 440.

In one embodiment, when the cleaning treatment is performed on the spacer 460, the cleaning treatment also removes a portion of the bottom dielectric layer 310 at the bottom corner of the opening 210, and therefore, during the step of performing the void compensation treatment at the bottom corner of the opening 210, the compensation layer 510 is further filled in the void defined by the bottom dielectric layer 310 and the substrate 100 at the bottom corners of the opening 210.

In one embodiment, in the step of forming the compensation layer 510 that fills the void at the bottom of the spacer 460, the material of the compensation layer 510 includes silicon nitride.

The use of silicon nitride to form the compensation layer 510 can achieve a better isolation effect, and the silicon nitride is harder and less damaged in the semiconductor process, which can guarantee the isolation effect of the compensation layer 510.

Specifically, referring to FIG. 9, the step of performing the void compensation treatment at the bottom corner of the opening 210 to form the compensation layer 510 that fills the void at the bottom of the spacer 460 comprises: forming a compensating material layer 500 covering the bottom of the opening 210, the sidewall of the spacer 460 on the sidewall of the opening 210, the top of the gate structure 200, and filling the void at the bottom of the spacer 460.

The compensating material layer 500 is used to form the compensation layer 510.

Specifically, in one embodiment, the compensating material layer 500 also fills the void at the top of the spacer 460, and the void in the bottom dielectric layer 310 at the bottom corner of the opening 210.

In one embodiment, in the step of forming a compensating material layer 500 covering the bottom of the opening 210, the sidewall of the spacer 460 on the sidewall of the opening 210, the top of the gate structure 200, and filling the void at the bottom of the spacer 460, the compensation material layer 500 has a thickness of 1 nm to 10 nm.

The thickness of the compensating material layer 500 is from 1 nm to 10 nm, so that the compensating material layer 500 can fill the voids more sufficiently and does not cause unnecessary material waste.

In one embodiment, using an atomic layer deposition (ALD) process to form the compensating material layer 500 covering the bottom of the opening 210, the sidewall of the spacer 460 on the sidewall of the opening 210, the top of the gate structure 200, and filling the void at the bottom of the spacer 460.

The thickness uniformity of the compensation material layer 500 formed by the atomic layer deposition process is good, and it has good step coverage capability; which enables the compensation material layer 500 to conformally cover the bottom of the opening 210, the sidewall of the spacer 460 on the sidewall of the opening 210, the top of the gate structure 200, and fill the void at the bottom of the spacer 460.

In other embodiments, it is also possible, using a Low Pressure Chemical Vapor Deposition (LPCVD) process to form the compensating material layer covering the bottom of the opening, the sidewall of the spacer on the sidewall of the opening, the top of the gate structure, and filling the void at the bottom of the spacer.

Referring to FIG. 10, removing the compensation material layer 500 covering the bottom of the opening 210, the sidewall of the spacer 460 on the sidewall of the opening 210, and the top of the gate structure 200, and retaining the compensation material layer that fills the void at the bottom of the spacer 460 as the compensation layer 510.

Specifically, in one embodiment, the compensating material layer 500 that fills the void at the top of the spacer 460, and the void in the bottom dielectric layer 310 at the bottom corner of the opening 210, is also retained as the compensation layer 510.

In one embodiment, using a wet etching process to remove the compensating material layer 500 covering the bottom of the opening 210, the sidewall of the spacer 460 on the sidewall of the opening 210, and the top of the gate structure 200.

The wet etching process is relatively low in cost and simple in operation steps, and also enables a large etching selectivity ratio, which facilitates the process of removing the compensating material layer 500 covering the bottom of the opening 210, the sidewall of the spacer 460 on the sidewall of the opening 210, and the top of the gate structure 200 in a manner that reduces damage to the other film layers.

In one embodiment, the etching solution of the wet etching process comprises a phosphoric acid solution.

The phosphoric acid has a high viscosity, usually 37.10 mPa·s, i.e., the phosphoric acid solution has a high viscosity, then the phosphoric acid solution is not easy to enter into the void, i.e., the phosphoric acid solution is not easy to react with the compensating material layer 500 in the void, so that the wet etching process is easy to remove the compensating material layer 500 that covers the bottom of the opening 210, the sidewall of the spacer 460 on the sidewall of the opening 210, and the top of the gate structure 200 when it is easy to keep the compensating material layer 500 in the void, thus favoring the formation of the compensation layer 510.

In one embodiment, the mass percentage of phosphoric acid in the phosphoric acid solution is from 40 wt % to 86 wt %.

The mass percentage of phosphoric acid in the phosphoric acid solution ranging from 40 wt % to 86 wt % facilitates the removal of the compensation material layer 500 covering the bottom of the opening 210, the sidewall of the spacer 460 on the sidewall of the opening 210, and the top of the gate structure 200, and it is easy to keep the viscosity high, so that the compensation material layer 500 in the void is easy to retain.

Specifically, in one embodiment, the mass percentage of phosphoric acid in the phosphoric acid solution is from 40 wt % to 60 wt %.

The mass percentage of phosphoric acid in the phosphoric acid solution is from 40 wt % to 60 wt %, which is favorable for lowering the etching rate and making the wet etching easier to control.

In one embodiment, the process temperature of the wet etching process is from 100° C. to 160° C.

The process temperature of the wet etching process is from 100° C. to 160° C., allowing for efficient etching while maintaining good etching quality:

Specifically, in one embodiment, the process temperature of the wet etching process is from 100° C. to 130° C.

The process temperature of the wet etching process is from 100° C. to 130° C., which favors a lower etching rate and makes wet etching easier to control.

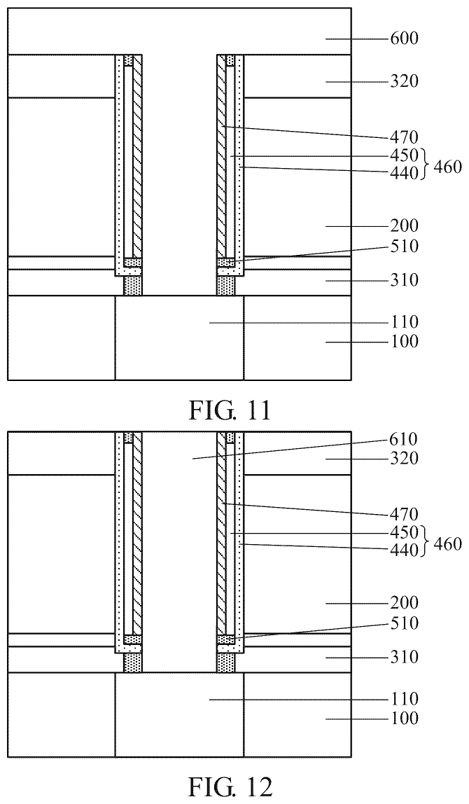

Referring in conjunction to FIGS. 11 and 12, forming a channel pillar 610 disposed on the substrate 100 and extending through the gate structure 200 in the opening 210.

The channel pillar 610 is used as the channel of the transistor.

Specifically, in one embodiment, the channel pillar 610 extends along the longitudinal direction through the gate structure 200, constituting a vertical channel transistor (VCT), which improves the integration degree of the transistor through the vertical channel design, allowing more transistors to be integrated in the same wafer area, thereby improving the performance and efficiency of the chip.

In one embodiment, the material of the channel pillar 610 includes silicon, germanium, silicon germanide, or a III-V semiconductor material. As an example, In one embodiment, the material of the channel pillar 610 is silicon. In other embodiments, the material of the channel pillar is determined based on the type and performance of the transistor.

Accordingly, in one embodiment, in the step of forming the channel pillar 610 disposed on the substrate 100 and extending through the gate structure 200 in the opening 210, the channel pillar 610 is in contact with the protective layer 470.

In one embodiment, the opening 210 exposes the top surface of the source-drain doping layer 110, and accordingly, in the step of forming the channel pillar 610 disposed on the substrate 100 and extending through the gate structure 200 in the opening 210, the channel pillar 610 is formed on and in contact with the source-drain doping layer 110.

In one embodiment, in the step of forming the channel pillar 610 disposed on the substrate 100 and extending through the gate structure 200 in the opening 210, the channel pillar 610 fills the opening 210.

Specifically, referring to FIG. 11, the step of forming the channel pillar 610 disposed on the substrate 100 and extending through the gate structure 200 in the opening 210 comprises: forming a channel material layer 600 that fills the opening 210 and covers the top of the top dielectric layer 320.

The channel material layer 600 is used to form the channel pillar 610.

Referring to FIG. 12, flattening the channel material layer 600 to remove the channel material layer 600 above the top dielectric layer 320 and retain the channel material layer 600 that fills the opening 210 as the channel pillar 610.

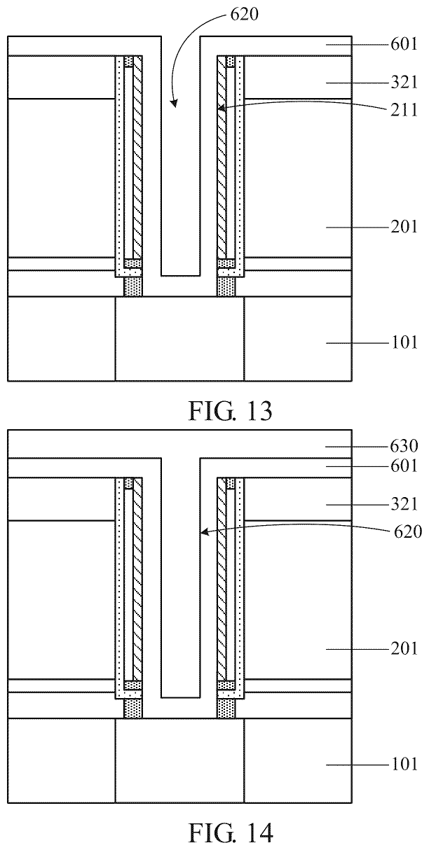

FIGS. 13 to 15 are schematic structural diagrams corresponding to each step in another embodiment of a fabrication method of a semiconductor structure according to the present disclosure.

The similarities between this embodiment and the preceding embodiments will not be repeated herein. The present embodiment differs from the preceding embodiments in that the structure of the channel pillar is different.

With reference to FIGS. 13 to 15, in the step of forming the channel pillar 611 disposed on the substrate 101 and extending through the gate structure 201 in the opening 211, on the top side of the channel pillar 611, a recess 620 is formed in the channel pillar 611 at a portion height.

The fact that the channel pillar 611 does not fill the area between the openings 211 facilitates a reduction in the probability of a concave shape on the top surface of the formed channel pillar 611.

In one embodiment, forming an insulating layer 640 that fills the recess 620.

Filling the recess 620 with an insulating layer 640 facilitates obtaining a top surface of the channel pillar 611 with a better surface flatness.

In one embodiment, in the step of forming the insulating layer 640 that fills the recess 620, the material of the insulating layer 640 is an insulating material including one or more of silicon oxide, silicon nitride, silicon nitride oxide, silicon carbon oxide, silicon carbon nitride, and silicon carbon nitride oxide.

Specifically, referring to FIG. 13, a channel material layer 601 is formed to cover the sidewall and bottom of the opening 211, and the top of the top dielectric layer 321, with a recess 620 defined by the channel material layer 601 in the opening 211.

The channel material layer 601 is used to form the channel pillar 611.

Referring to FIG. 14, forming an insulating material layer 630 to fill the recesses 620, and to cover the channel material layer 601.

The insulating material layer 630 is used to form the insulating layer 640.

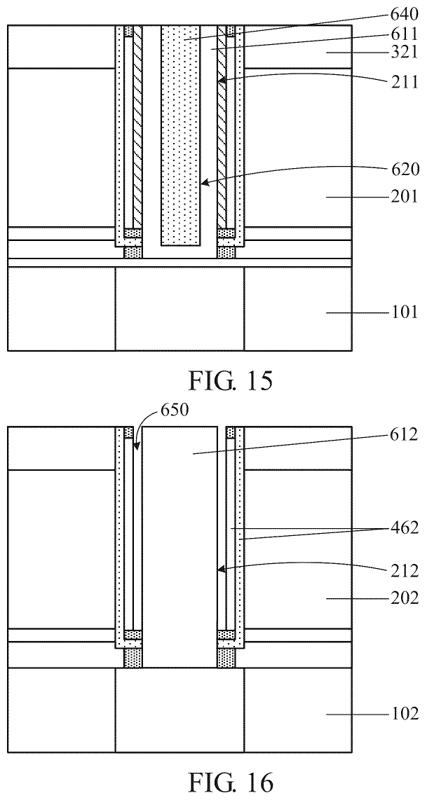

Referring to FIG. 15, flattening the insulating material layer 630 and the channel material layer 601 removes the insulating material layer 630 and the channel material layer 601 above the top dielectric layer 321, retaining the channel material layer 601 in the opening 211 as the channel pillar 611, and retaining the insulating material layer 630 in the opening 211 as the insulating layer 640.

FIG. 16 is a schematic structural diagram corresponding to each step in yet another embodiment of a fabrication method of a semiconductor structure according to the present disclosure.

The similarities between this embodiment and the preceding embodiments will not be repeated herein. This embodiment differs from the preceding embodiments in that the protective layer is removed.

Referring to FIG. 16, after forming the channel pillar 612 disposed on the substrate 102 and extending through the gate structure 202 in the opening 212, further comprising: removing the protective layer to form an air gap 650 disposed between the spacer 462 and the sidewall of the channel pillar 612.

The air gap 650 is used to serve, along with the sidewall 462, to isolate the gate structure 202 from the channel pillars 612.

In one embodiment, the air gap 650 and the spacer 462 together isolate the gate structure 202 from the channel pillar 612, and the dielectric constant of the air is low, then the use of the air gap 650 together with the spacer 462 to isolate the gate structure 202 from the channel pillar 612 is conducive to lowering the dielectric constant of the overall isolation between the gate structure 202 and the channel pillar 612, which is conducive to lowering the parasitic capacitance and improving the semiconductor structure's operating performance.

Although disclosed as above, the present disclosure is not limited to the foregoing description. A person skilled in the art can make various changes and modifications without departing from the spirit and the scope of the present disclosure. Thus, the scope of protection of the present disclosure should be subject to the scope defined by the claims.

What is claimed is:

1. A semiconductor structure, comprising:
a substrate;
a gate structure, disposed on the substrate;
a channel pillar, disposed on the substrate and extending through the gate structure in the longitudinal direction;
a spacer, extending longitudinally between the sidewall of the channel pillar and the gate structure;
a compensation layer, filling the void between the channel pillar and the gate structure at the bottom position of the spacer.

2. The semiconductor structure according to claim 1, further comprising: a spacing layer, disposed between the spacer and the sidewall of the channel pillar;
the compensation layer is also filled in the void between the channel pillar and the gate structure at the bottom position of the spacing layer.

3. The semiconductor structure according to claim 2, wherein:
the spacing layer is a protective layer, the protective layer covers the sidewall of the spacer;
or,
the spacing layer is an air gap.

4. The semiconductor structure according to claim 3, wherein the spacing layer is a protective layer, the material of the protective layer includes amorphous silicon, polycrystalline silicon, a combination of polycrystalline silicon with silicon oxide and tungsten or a combination of polycrystalline silicon with silicon oxide and titanium nitride.

5. The semiconductor structure according to claim 2, wherein the compensation layer is further filled in a void defined by the top of the spacer and the spacing layer.

6. The semiconductor structure according to claim 5, wherein the spacer comprises a first spacer covering the sidewall of the gate structure, and a second spacer covering the sidewall of the first spacer;
at the bottom of the spacer, the void filled by the compensation layer is defined by the bottom of the second spacer, the bottom of the spacing layer, the first spacer, and the sidewall of the channel pillar;
at the top of the spacer, the void filled by the compensation layer is defined by the top of the second spacer, the sidewall of the spacing layer, and the sidewall of the first spacer.

7. The semiconductor structure according to claim 1, wherein the material of the compensation layer includes silicon nitride.

8. The semiconductor structure according to claim 1, further comprising: a top dielectric layer, covering the top surface of the gate structure;
a bottom dielectric layer, disposed between the gate structure and the substrate;
the channel pillar also extends through the top dielectric layer and bottom dielectric layer;
the spacer also extends between the sidewall of the channel pillar and the top dielectric layer;
the compensation layer is also filled in the void between the channel pillar and the bottom dielectric layer.

9. The semiconductor structure according to claim 1, wherein on the top side of the channel pillar, a recess is formed in the channel pillar at a portion height, the semiconductor structure further comprising: an insulating layer, filled in the recess.

10. A fabrication method of a semiconductor structure, comprising:
providing a substrate, the substrate having a gate structure formed thereon;
forming an opening through the gate structure;
forming a spacer covering the sidewall of the opening;
performing a void compensation treatment at the bottom corner of the opening to form a compensation layer that fills the void at the bottom of the spacer;
forming a channel pillar disposed on the substrate and extending through the gate structure in the opening.

11. The fabrication method according to claim 10, wherein before performing the void compensation treatment at the bottom corner of the opening, further comprising: forming a protective layer covering the sidewall of the spacer;
in the step of performing the void compensation treatment at the bottom corner of the opening, the compensation layer is further filled in the void at the bottom of the protective layer at the bottom corner of the opening;
in the step of forming the channel pillar disposed on the substrate and extending through the gate structure in the opening, the channel pillar is in contact with the protective layer.

12. The fabrication method according to claim 11, wherein after forming the channel pillar disposed on the substrate and extending through the gate structure in the opening, further comprising: removing the protective layer to form an air gap disposed between the spacer and the sidewall of the channel pillar.

13. The fabrication method according to claim 11, wherein in the step of performing the void compensation treatment at the bottom corner of the opening, the compensation layer is also filled in the void defined by the top of the spacer and the protective layer.

14. The fabrication method according to claim 13, wherein the step of forming the spacer covering the sidewall of the opening comprises: forming a spacer material layer covering the sidewall and bottom of the opening, and the top of the gate structure;
removing the spacer material layer at the bottom of the opening and at the top of the gate structure, and retaining the spacer material layer covering the sidewall of the opening as the spacer.

15. The fabrication method according to claim 14, wherein in the step of providing the substrate, a top dielectric layer is also formed on top of the gate structure, and a bottom dielectric layer is also formed between the gate structure and the substrate;
in the step of forming an opening through the gate structure, the opening also extends through the top dielectric layer, and the opening also extends through a portion thickness of the bottom dielectric layer;
in the step of removing the spacer material layer at the bottom of the opening and at the top of the gate structure, further comprises: removing the remaining portion of the thickness of the bottom dielectric layer to expose the top surface of the substrate;
in the step of performing the void compensation treatment at the bottom corner of the opening, the compensation layer is further filled in the void defined by the bottom dielectric layer and the substrate at the bottom corner of the opening.

16. The fabrication method according to claim 14, wherein the step of forming the spacer material layer covering the sidewall and bottom of the opening, and the top of the gate structure comprises: forming a first spacer material layer covering the sidewall and bottom of the opening, and the top of the gate structure;
forming a second spacer material layer covering the first spacer material layer;
in the step of removing the spacer material layer at the bottom of the opening and at the top of the gate structure, the first spacer material layer and the second spacer material layer at the bottom of the opening and at the top of the gate structure are removed, the first spacer material layer covering the sidewall of the opening being retained as a first spacer, and the second spacer material layer covering the sidewall of the opening being retained as a second spacer;
in the step of performing the void compensation treatment at the bottom corner of the opening, the compensation layer is filled in the void defined by the bottom of the second spacer, the bottom of the protective layer, and the first spacer, and the compensation layer is further filled in the void defined by the top of the second spacer, the sidewall of the protective layer, and the sidewall of the first spacer.

17. The fabrication method according to claim 14, wherein before removing the spacer material layer at the bottom of the opening and at the top of the gate structure, further comprising: forming a protective material layer covering the spacer material layer;
the step of removing the spacer material layer at the bottom of the opening and at the top of the gate structure further comprises: removing the protective material layer at the bottom of the opening and at the top of the gate structure, retaining the protective material layer covering the sidewall of the spacer as the protective layer.

18. The fabrication method according to claim 17, wherein using a dry etching process to remove the spacer material layer at the bottom of the opening and at the top of the gate structure;
after removing the spacer material layer at the bottom of the opening and at the top of the gate structure, and before performing the void compensation treatment at the bottom corner of the opening, further comprising: performing a cleaning treatment on the spacer.

19. The fabrication method according to claim 10, wherein the step of performing the void compensation treatment at the bottom corner of the opening to form the compensation layer that fills the void at the bottom of the spacer comprises: forming a compensating material layer covering the bottom of the opening, the sidewall of the spacer on the sidewall of the opening, the top of the gate structure, and filling the void at the bottom of the spacer;
removing the compensating material layer covering the bottom of the opening, the sidewall of the spacer on the sidewall of the opening, and the top of the gate structure, and retaining the compensating material layer that fills the void at the bottom of the spacer as the compensation layer.

20. The fabrication method according to claim 10, wherein in the step of forming the channel pillar disposed on the substrate and extending through the gate structure in the opening, the channel pillar fills the opening;
or, in the step of forming the channel pillar disposed on the substrate and extending through the gate structure in the opening, on the top side of the channel pillar, a recess is formed in the channel pillar at a portion height;
forming an insulating layer that fills the recess.
